(19) United States
(12) Patent Application Publication
(10) Pub. No.: US 2015/0103268 A1
(43) Pub. Date: Apr. 16, 2015

(54) DISPLAY DEVICE EQUIPPED WITH TOUCH PANEL

(71) Applicant: Sharp Kabushiki Kaisha, Osaka (JP)

(72) Inventor: Noriko Watanabe, Osaka (JP)

(73) Assignee: Sharp Kabushiki Kaisha, Osaka (JP)

(21) Appl. No.: 14/395,789

(22) PCT Filed: Apr. 24, 2013
(86) PCT No.: PCT/JP2013/062038

§ 371 Date: Oct. 20, 2014

(30) Foreign Application Priority Data
Apr. 27, 2012 (JP) 2012-102495

(51) Int. Cl. G06F 3/044; H01L 27/32; G02F 1/1333

(52) U.S. Cl. CPC G06F 3/044; G02F 1/13338; G02F 1/133305; H01L 27/323
USPC 349/12

(57) ABSTRACT

The purpose of the present invention is to provide a display device equipped with a touch panel that can prevent damage to the transparent conductive film or the like provided on the film substrate when reworking takes place. A liquid crystal display device equipped with a touch panel is provided with: a liquid crystal display panel having a liquid crystal display element; an adhesive layer provided on the liquid crystal display panel; and a touch panel having a flexible film substrate provided on the adhesive layer and a touch panel electro-conductive film provided on the film substrate, the touch panel being affixed to the liquid crystal display panel via the adhesive layer. In a plan view, the outer shape of the adhesive layer is configured to be larger than the outer shape of the touch panel.

### TECHNICAL FIELD

The present invention relates to a display device equipped with a touch panel that can detect a touch location where a pen, a finger, or the like touches a display surface.

### BACKGROUND ART

Recently, touch panels (or touch sensors) are provided in electronic devices such as vending machines, ATMs, portable gaming devices, and car navigation systems to control such devices by touching the screen.

These touch panels are an interactive device that inputs information to an electronic device by touching (applying pressure to) the touch panel with a finger, pen, or the like.

Furthermore, touch panels are categorized according to their operating principles into a resistive type, a capacitive type, an infrared type, an ultrasonic type, an electromagnetic type, or the like. Recently, resistive type and capacitive type touch panels are often used because they are low-cost and can be mounted on display devices and the like.

Furthermore, in general, if a touch panel and a display panel are integrally used, the touch panel is disposed on the front face (side of the viewer) of the display panel such as a liquid crystal display panel, for example.

Recently, in the field of display, touch panels using film substrates that have a great advantage over glass substrates in terms of flexibility, shock resistance, and lightness have been gaining attention.

A configuration disclosed for a display device provided with this type of touch panel includes a TFT (thin film transistor) substrate, a CF (color filter) substrate disposed towards the viewer, a liquid crystal display panel formed of a TFT substrate, a CF substrate, and a liquid crystal layer sandwiched therebetween, a first film substrate provided on the surface opposite to the side where the liquid crystal layer on the CF substrate is disposed, a first transparent conductive film for a touch panel provided on the first film substrate as a resistance film, a second film substrate provided so as to face the first film substrate, and a second transparent conductive film for a touch panel provided on the second film substrate as a resistance film. In this configuration, the touch panel is bonded to the liquid crystal display panel through an adhesive layer such as an adhesive tape, for example (see Patent Document 1, for example).

### RELATED ART DOCUMENT

### Patent Document

Patent Document 1: Japanese Patent Application Laid-Open Publication No. 2005-115729

### SUMMARY OF THE INVENTION

### Problems to be Solved by the Invention

When the touch panel is being bonded, in some cases air and foreign material are sandwiched between the touch panel and the liquid crystal display panel, causing air bubbles and display anomalies. Therefore, the liquid crystal display panel that has a touch panel bonded thereto with air bubbles needs reworking in which the touch panel on the liquid crystal display panel is removed and the touch panel is bonded to the liquid crystal display panel again.

However, like the display device disclosed in Patent Document 1, if the touch panel itself is peeled off in a display device provided with a touch panel using a film substrate when reworking is performed, the touch panel deforms greatly due to local stress because the film substrate has high adhesiveness to the adhesive layer and has flexibility, making it more likely a transparent conductive film or the like provided on the touch panel will be damaged. Therefore, previously there was a problem in that reworking was difficult.

The present invention is made in view of the above-mentioned problems, and the object thereof is to provide a display device equipped with a touch panel that can prevent damage to the transparent conductive film or the like provided on the film substrate when reworking takes place.

### Means for Solving the Problems

To achieve the above-mentioned goals, a display device equipped with a touch panel in the present invention includes: a display panel provided with a display element; an adhesive layer provided on the display panel; and a touch panel having a flexible film substrate disposed on the adhesive layer and a conductive film for the touch panel disposed on the flexible film substrate, the touch panel being bonded to the display panel via the adhesive layer, wherein an outer shape of the adhesive layer is larger than an outer shape of the touch panel in a plan view.

According to the same configuration, if the touch panel provided with the film substrate is removed from the display panel through reworking, then the touch panel can be removed from the display panel by peeling off the adhesive layer through gripping the outer edge portion of the adhesive layer. Therefore, it would not be necessary to peel off the touch panel by gripping the touch panel itself, and thus the touch panel can be prevented from deforming greatly due to the local stress caused during the removal. As a result, when the reworking of the touch panel provided with a film substrate takes place, the reworking can be done without causing damage to the conductive film or the like provided on the touch panel.

In the display device equipped with a touch panel of the present invention, the touch panel may further include: another flexible film substrate disposed on the touch panel so as to face the flexible film substrate; another conductive film for the touch panel provided on a surface of the another film substrate on a side facing the film substrate; another adhesive layer provided on a surface of the another flexible film substrate opposite to the display panel; and a protective plate bonded to the touch panel via the another adhesive layer, and wherein an outer shape of the another adhesive layer is larger than an outer shape of the touch panel in a plan view.

According to the same configuration, if the touch panel is removed from the protective plate provided with another film substrate, then the touch panel can be removed from the protective plate by peeling off another adhesive layer by gripping the outer edge portion of the another adhesive layer. Therefore, it would not be necessary to peel off the touch panel by gripping the touch panel itself, and thus the touch panel can be prevented from deforming greatly because of the local stress caused during the removal. As a result, when the reworking of the touch panel provided with the another film substrate takes place, the reworking can be done without causing damage to the another conductive film or the like provided on the touch panel.

In the display device equipped with a touch panel of the present invention, the protective plate may be a glass panel.

In the display device equipped with a touch panel of the present invention, the display element may be a liquid crystal display element.

According to the same configuration, the display device equipped with a touch panel provided with a liquid crystal display element can be reworked without causing damage to the conductive film or the like provided on the touch panel when the reworking of the touch panel provided with a film substrate takes place.

In the display device equipped with a touch panel of the present invention, the display element may be an organic electroluminescent display element.

According to the same configuration, the display device equipped with a touch panel provided with an organic EL display element can be reworked without causing damage to the conductive film or the like provided on the touch panel when the reworking of the touch panel provided with a film substrate takes place.

In the display device equipped with a touch panel of the present invention, the touch panel may be a capacitive type touch panel.

According to the same configuration, the display device equipped with a capacitive type touch panel can be reworked without causing damage to the conductive film or the like provided on the touch panel when the reworking of the touch panel provided with a film substrate takes place.

### Effects of the Invention

According to the present invention, reworking can take place for the liquid crystal display device equipped with a touch panel provided with a film substrate without damaging the conductive film or the like provided on the touch panel during the reworking of the touch panel.

### BRIEF DESCRIPTION OF THE DRAWINGS

FIG. 1 is a plan view showing a liquid crystal display device equipped with a touch panel according to Embodiment 1 of the present invention.

FIG. 2 is a cross-sectional view of FIG. 1 along the line A-A.

FIG. 3 is a cross-sectional view describing a method for reworking the touch panel according to Embodiment 1 of the present invention.

FIG. 4 is a cross-sectional view describing a method for reworking the touch panel according to Embodiment 1 of the present invention.

FIG. 5 is a cross-sectional view describing a method for reworking the touch panel according to Embodiment 1 of the present invention.

FIG. 6 is a plan view showing a liquid crystal display device equipped with a touch panel according to Embodiment 2 of the present invention.

FIG. 7 is a cross-sectional view of FIG. 6 along the line B-B.

FIG. 8 is a cross-sectional view describing a method for reworking the touch panel according to Embodiment 2 of the present invention.

FIG. 9 is a cross-sectional view describing a method for reworking the touch panel according to Embodiment 2 of the present invention.

FIG. 10 is a cross-sectional view describing a method for reworking the touch panel according to Embodiment 2 of the present invention.

FIG. 11 is a cross-sectional view describing a method for reworking the touch panel according to Embodiment 2 of the present invention.

### DETAILED DESCRIPTION OF EMBODIMENTS

### Embodiment 1

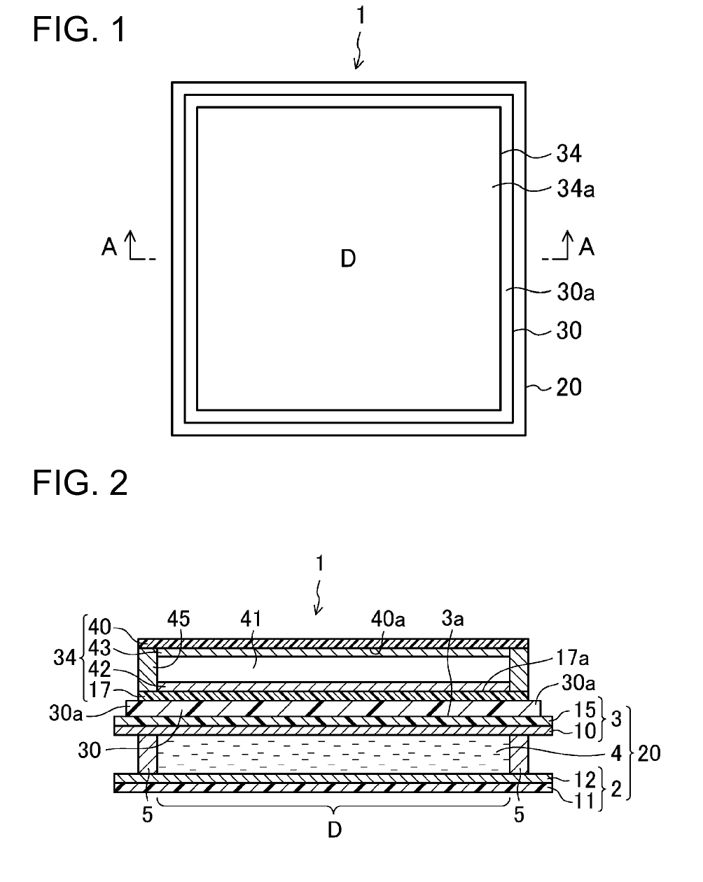

Embodiments of the present invention will be described in detail below with reference to drawings. FIG. 1 is a plan view showing a liquid crystal display device equipped with a touch panel according to Embodiment 1 of the present invention, and FIG. 2 is a cross-sectional view of FIG. 1 along the line A-A.

As shown in FIGS. 1 and 2, a liquid crystal display device 1 is provided with a liquid crystal display panel 20 having: a TFT substrate 2 on which a plurality of TFTs (thin film transistors) that are switching elements are formed; a CF substrate 3 disposed so as to face the TFT substrate 2; a liquid crystal layer 4 that is a display medium layer provided so as to be sandwiched between the TFT substrate 2 and the CF substrate 3; and a frame-shaped sealing member 5 that is sandwiched between the TFT substrate 2 and the CF substrate 3 and that adheres the TFT substrate 2 and the CF substrate 3 together while sealing the liquid crystal layer 4 therebetween.

The sealing member 5 is formed around the liquid crystal layer 4 such that the TFT substrate 2 and the CF substrate 3 are bonded to each other through the sealing member 5. The TFT substrate 2 and the CF substrate 3 are both formed in a rectangular plate shape.

Furthermore, the liquid crystal display panel 20 has a plurality of photospacers (not shown) that restrict the thickness (cell gap) of the liquid crystal layer 4 are sandwiched between the TFT substrate 2 and the CF substrate 3. These photospacers are made of an acrylic photosensitive resin and formed by photolithography, for example.

Furthermore, as shown in FIGS. 1 and 2, a display region (coordinate input region for the touch panel) D that performs image display in the liquid crystal display device 1 is defined by the region within the sealing member 5 where the TFT substrate 2 and the CF substrate 3 overlap. A plurality of pixels, the smallest unit of an image, are arranged in a matrix in the display region D.

The TFT substrate 2 is provided with a plastic substrate 11 that is a flexible insulating substrate having a film shape and formed of a resin material. Organic material that can be used as the resin material forming the plastic substrate 11 includes a polyimide resin, a polyethylene terephthalate resin, a polyether sulfone resin, polyparaxylene, or an acrylic resin.

Furthermore, a display element layer 12 provided with TFTs or the like is formed on the plastic substrate 11 of the TFT substrate 2.

The display element layer 12 has a plurality of gate lines (not shown) that extend so as to be parallel to each other on the plastic substrate 11, a plurality of source lines (not shown) that extend so as to be parallel to each other and perpendicular to the respective gate lines, a plurality of TFTs (not shown) provided on the respective intersections of the gate lines and the source lines, a plurality of pixel electrodes (not shown) connected to the respective TFTs, and an alignment film (not shown) provided on the pixel electrodes.

The CF substrate 3, similar to the TFT substrate 2, is provided with a plastic substrate 15 that is a flexible insulating substrate having a film shape and formed of a resin material. The resin material that forms the plastic substrate 15 may use a material similar to the organic material forming the plastic substrate 11 mentioned above.

Furthermore, a CF element layer 10 is formed on the plastic substrate 15 of the CF substrate 3. The CF element layer 10 is provided with a plurality of colored layers (not shown) that are respectively colored into red, green, or blue in respect to respective pixel electrodes on the TFT substrate 2, a color filter formed of a black matrix (not shown) provided between the respective colored layers, an overcoat layer (not shown) provided on the color filter, a common electrode (not shown) provided on the overcoat layer (not shown), and an alignment film (not shown) provided on the common electrode.

The configuration of the liquid crystal display panel 20 of the present embodiment has a liquid crystal display element constituted of a pixel electrode, the liquid crystal layer 4 formed on the pixel electrode, and a common electrode formed on the liquid crystal layer 4.

It is preferable that the thickness of the plastic substrates 11 and 15 be greater than or equal to 3 μm. This is because if the thickness is less than 3 μm, the mechanical strength obtained may not be sufficient.

The liquid crystal layer 4 includes a nematic liquid crystal having electrooptic characteristics, for example.

Furthermore, as shown in FIGS. 1 and 2, the liquid crystal display device 1 of the present embodiment is a liquid crystal display device equipped with a touch panel of a resistive type, and an adhesive layer 30 is provided on a surface 3a of the CF substrate 3 on the side opposite to the liquid crystal layer 4. A touch panel 34 is bonded to the display panel 20 through the adhesive layer 30.

More specifically, as shown in FIG. 2, a film substrate 17 that is flexible is provided on the adhesive layer 30, and a film substrate 40 that is flexible is disposed so as to face the film substrate 17 with an air layer 41 therebetween.

The resin material used for the film substrates 17 and 40, similar to the plastic substrate 11 and 15, can use an organic material such as a polyimide resin, a polyethylene terephthalate resin, a polyether sulfone resin, polyparaxylene, an acrylic resin, or the like.

Furthermore, the adhesive layer 30 is formed of an adhesive made of an acrylic adhesive that is polymerized with butyl acrylate, or a silicon resin, for example.

Furthermore, on a surface 17a of the film substrate 17 that is opposite to the liquid crystal display panel 20, a conductive film 42 for the touch panel configuring the resistive type is provided. Furthermore, on a surface 40a of the film substrate 40 in the liquid crystal display panel 20 (namely, surface on the film substrate 17 side), a conductive film 43 for a touch panel is provided so as to form a resistive type touch panel.

This configuration may be provided with a plurality of dot spacers (not shown) between the conductive films 42 and 43 in order to prevent the conductive films 42 and 43 from coming into contact unintentionally due to a warp in the film substrate 40 caused by external factors.

Furthermore, the film substrate 17 and the film substrate 40 are formed so as to be bonded to each other by a bonding material 45 provided in the air layer 41.

In the present embodiment, as shown in FIG. 1, the touch panel 34 is formed of the film substrate 17, the film substrate 40, the conductive films 42 and 43, and the dot spacers.

The touch panel 34 is provided with a plurality of terminals (not shown) and wiring lines (not shown) that are respectively connected to the plurality of terminals. Furthermore, the touch panel 34 is connected to the terminals, and a flexible printed circuit board (not shown) that is a driver circuit substrate for supplying the signals from outside to the touch panel 34 is attached thereon.

Furthermore in the present embodiment, on the surface 3a of the CF substrate 3 that is opposite to the liquid crystal layer 4, a polarizing plate (not shown) is provided, and the touch panel 34 is provided on the surface of the polarizing plate. Similarly, a polarizing plate (not shown) is provided on the surface of the touch panel 34 on the opposite side to the liquid crystal display panel 20. This polarizing plate is an optical sheet that has a function to transmit only the polarization component of a particular direction.

Once the surface of the film substrate 40 is pressed via the polarizing plate, the resistive type touch panel with this type of configuration detects positions by the pair of conductive films 42 and 43 making contact (short-circuiting) with each other, a current flowing between these pair of conductive films 42 and 43, and the change in voltage (change in resistance) when the current flows between these pair of conductive films 42 and 43 being detected.

As shown in FIGS. 1 and 2 in the present embodiment, the outer shape of the adhesive layer 30 is larger than the outer shape of the touch panel 34 in a plan view (in other words, an outer edge portion 30a of the adhesive layer 30 protrudes farther outwards than an outer edge portion 34a of the touch panel 34, in a plan view).

With this type of configuration, if the touch panel 34 provided with the film substrates 17 and 40 is removed from the liquid crystal display panel 20 through reworking, the touch panel 34 can be removed by removing the adhesive layer 30 by gripping the outer edge portion 30a of the adhesive layer 30.

Therefore, there is no need to grip the outer edge portion 34a of the touch panel 34 to remove the touch panel 34, and therefore the touch panel 34 can be prevented from greatly deforming due to local stress caused during the removal. As a result, when reworking of the touch panel 34 provided with the film substrates 17 and 40 takes place, the reworking can be performed without causing damage to the conductive films 42 and 43 provided on the touch panel 34, the wirings, and the like.

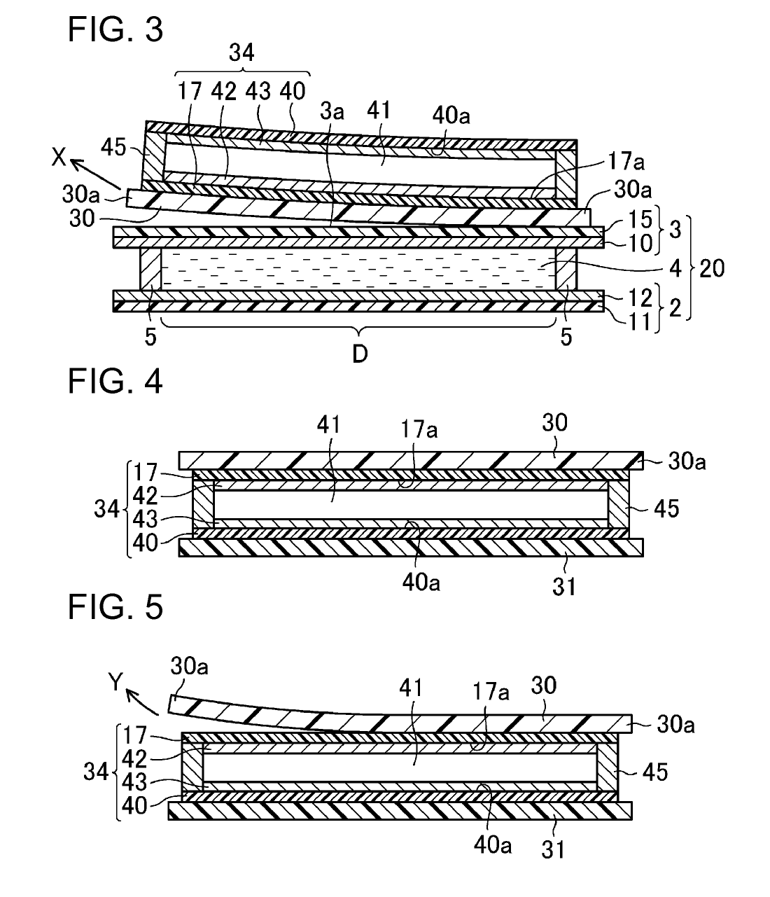

Next, a specific method of reworking the touch panel is described. FIGS. 3 to 5 are cross-sectional views describing a method for reworking the touch panel according to Embodiment 1 of the present invention.

First, as shown in FIG. 3, the touch panel 34 is removed from the liquid crystal display panel 20 by removing the adhesive layer 30 in the direction of the arrow X in the figure while the outer edge portion 30a of the adhesive layer 30 is being gripped.

During this time, as shown in FIG. 3, the touch panel 34 can be prevented from deforming greatly due to local stress caused during the removal of the touch panel 34 by gripping the touch panel 34.

Next, as shown in FIG. 4, the touch panel 34 having the adhesive layer 30 is fixed to the film 31 by laminating the film substrate 40 of the touch panel 34 with the film 31 having weak adhesive property.

A film having an adhesive layer with weak adhesive property on the surface of a polyester film can be used as the film 31 with weak adhesive property, for example.

Next, as shown in FIG. 5, while the touch panel 34 is fixed to the film 31, the adhesive layer 30 is removed from the touch panel 34 by gripping the outer edge portion 30a of the adhesive layer 30 and peeling off the adhesive layer 30 in the Y direction of the figure.

Then, a new adhesive layer is provided on the surface of the liquid crystal display panel 20 (namely, on the surface 3a of the CF substrate 3 provided with the adhesive layer 30 that was removed, the surface 3a being on the side opposite to the liquid crystal layer 4 side).

Then, the reworking of the touch panel 34 is completed by bonding the touch panel 34 (with the adhesive layer 30 being removed) to the surface 3a of the CF substrate 3 on the side opposite to the liquid crystal layer 4 via this new adhesive layer.

In a similar manner to the liquid crystal display device 1 equipped with a touch panel shown in FIGS. 1 and 2, when the touch panel 34 is being bonded, the touch panel 34 is bonded such that the outer shape of the new adhesive layer is larger than the outer shape of the touch panel 34 in a plan view. Reworking can be performed again with this type of configuration.

### Embodiment 2

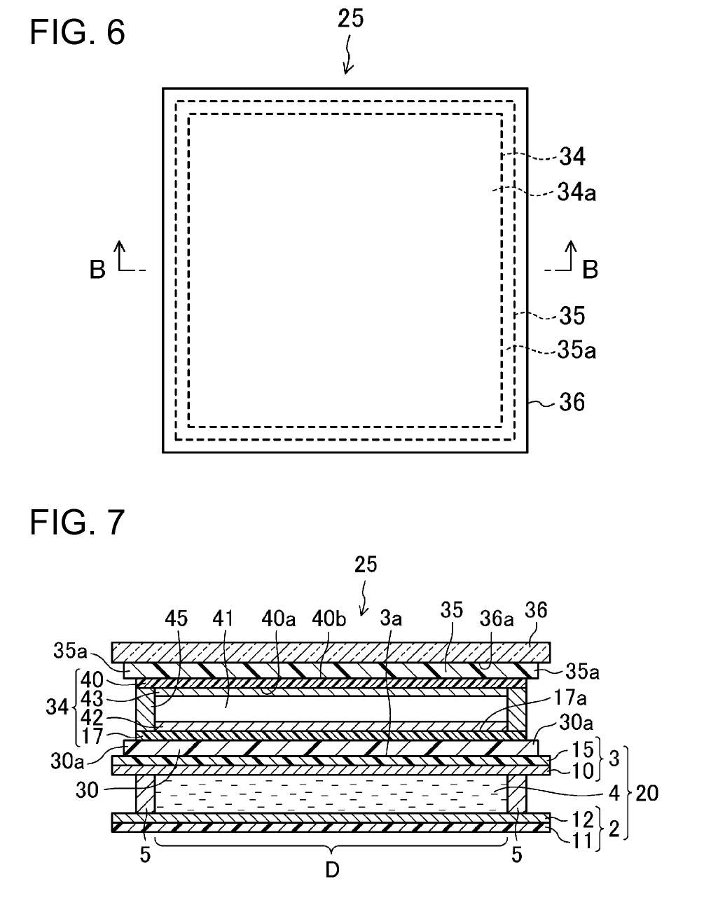

Next, Embodiment 2 of the present invention will be described. FIG. 6 is a plan view showing a liquid crystal display device equipped with a touch panel according to Embodiment 2 of the present invention, and FIG. 7 is a cross-sectional view along the line B-B of FIG. 6. In the present embodiment, constituent portions similar to those of Embodiment 1 are assigned the same reference characters and descriptions thereof are omitted.

As shown in FIGS. 6 and 7, a liquid crystal display device 25 equipped with a touch panel of the present embodiment is provided with an adhesive layer 35 on the surface of a touch panel 34 (namely, a surface 40b of a film substrate 40 on a side opposite to a liquid crystal display panel 20) and a protective plate 36 for protecting the touch panel 34 is bonded to the touch panel 34 via the adhesive layer 35.

A glass panel or the like can be used as this protective plate 36. Furthermore, the adhesive layer 35 used can be similar to the above-mentioned adhesive layer 30.

As shown in FIGS. 6 and 7, the adhesive layer 35 is characterized by having an outer shape larger than that of the touch panel in a plan view (in other words, an outer edge portion 35a of the adhesive layer 35 protrudes farther outwards than the outer edge portion 34a of the touch panel 34).

In this type of configuration, if the touch panel 34 provided with a film substrate 40 is being removed from the protective plate 36 through reworking, then the touch panel 34 can be removed from the protective plate 36 by peeling off the adhesive layer 35 while gripping the outer edge portion 35a of the adhesive layer 35.

Therefore, there is no need to grip the outer edge portion 34a of the touch panel 34 to remove the touch panel 34, and therefore the touch panel 34 can be prevented from greatly deforming due to local stress caused during the removal. As a result, when reworking of the touch panel 34 provided with film substrates 17 and 40 is performed, the reworking can be performed without causing damage to the conductive films 42 and 43, the wirings, and the like provided on the touch panel 34.

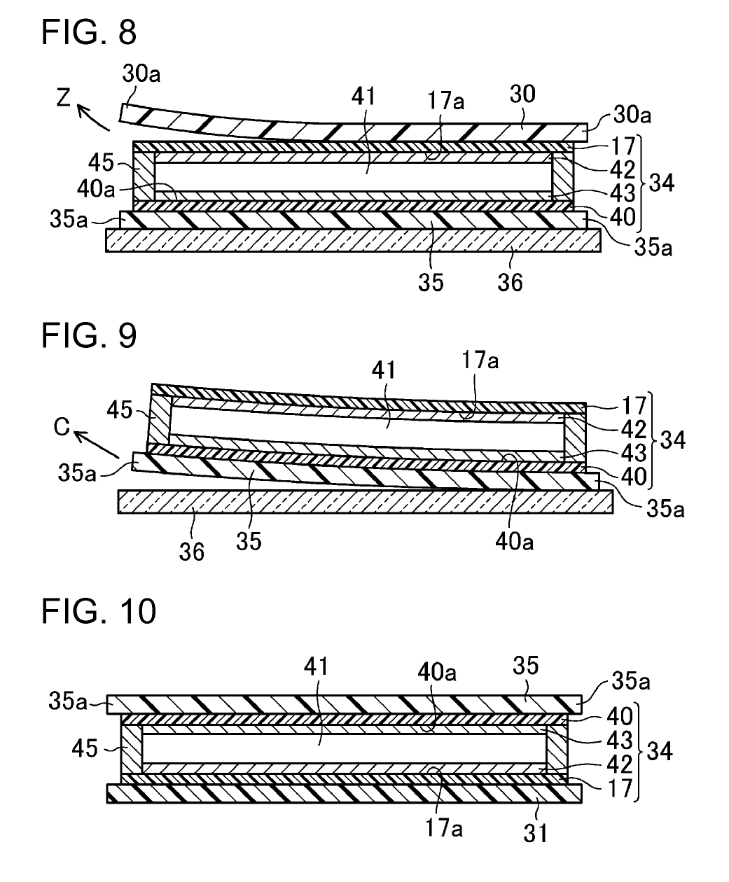

Next, a specific method of reworking the touch panel is described. FIGS. 8 to 11 are cross-sectional views describing a method for reworking the touch panel according to Embodiment 2 of the present invention.

First, in a similar manner to Embodiment 1 mentioned above, the touch panel 34 is removed from the liquid crystal display panel 20.

Then, the adhesive layer 30 is removed from the touch panel 34. At this time, in Embodiment 1 mentioned above, while the touch panel 34 having the adhesive layer 30 is fixed to the film 31 by laminating the film substrate 40 of the touch panel 34 with the film 31 having weak adhesive property, the adhesive layer 30 is removed from the touch panel 34 by gripping the outer edge portion 30a of the adhesive layer 30 and peeling off the adhesive layer 30. However, in the present embodiment, the protective plate 36 bonded to the touch panel 34 has high rigidity and is flat, and as shown in FIG. 8, while the touch panel 34 is fixed to the protective plate 36, the adhesive layer 30 is removed from the touch panel 34 by gripping the outer edge portion 30a of the adhesive layer 30 and peeling off the adhesive layer 30 in the Z direction of the figure.

Then, as shown in FIG. 9, the touch panel 34 is removed from the protective plate 36 by removing the adhesive layer 35 in the direction of the arrow C in the figure as the outer edge portion 35a of the adhesive layer 35 is being gripped.

During this time, as shown in FIG. 9, the touch panel 34 can be prevented from deforming greatly due to local stress caused during the removal of the touch panel 34 by gripping the touch panel 34.

Next, as shown in FIG. 10, the film substrate 17 of the touch panel 34 is laminated by the film 31 having weak adhesive property, and the touch panel 34 having the adhesive layer 35 is fixed to the film 31.

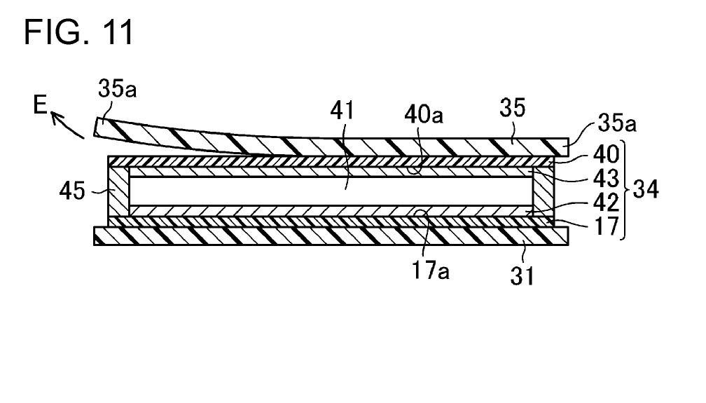

Next, as shown in FIG. 11, the adhesive layer 35 is removed from the touch panel 34 by gripping the outer edge portion 35a of the adhesive layer 35 while the touch panel 34 is fixed to the film 31 and then peeling off the adhesive layer 35 in the E direction of the figure.

Then, a new adhesive layer is provided on the surface of the liquid crystal display panel 20 (namely, on the surface 3a of the CF substrate 3 with the adhesive layer 30 that was removed, the surface 3a being on the side opposite to the liquid crystal layer 4).

Then, the touch panel 34 with the adhesive layer 30 being removed is attached to the surface 3a of the CF substrate 3 on the side opposite to the liquid crystal layer 4 via this new adhesive layer.

Furthermore, another adhesive layer is provided on the surface of the protective plate 36 (namely, on a surface 36a towards the touch panel 34 where the removed adhesive layer 35 was provided).

Then, the reworking of the touch panel 34 is completed by bonding the touch panel 34 (with the adhesive layer 35 being removed) to the surface 36a of the protective plate 36 on the touch panel 34 side via this new adhesive layer.

In a similar manner to the liquid crystal display device 25 equipped with a touch panel shown in FIGS. 6 and 7, when the touch panel 34 is being bonded, the touch panel 34 is bonded such that the outer shape of the new adhesive layer is larger than the outer shape of the touch panel 34 in a plan view. Reworking can be performed again with this type of configuration.

The embodiments above may be modified in the following manner.

In the embodiments mentioned above, examples with a resistive type touch panel were given, but the present invention may also use a capacitive type touch panel.

A configuration having a film substrate, a conductive film that sets the input region provided in a rectangular shape on the film substrate, a terminal for external connection provided in a terminal region, and a wiring line electrically connected to a terminal is one example of this type of capacitive type touch panel.

Furthermore, in a capacitive type touch panel, an alternating current voltage is applied to a terminal for location detection, and when a contact point is formed on the conductive film with a finger, pen, or the like, the conductive film is capacitively coupled with ground (ground plane) and the position coordinates of the portion in contact is obtained by detecting the current between the contact portion that is capacitively coupled and the terminal.

In addition, by applying the present invention to a display device equipped with a touch panel that is a capacitive type, the capacitive type display device equipped with a touch panel display device can be reworked without causing damage to the conductive film or the like provided on the touch panel when the reworking of the touch panel provided with a film substrate takes place.

In the respective embodiments above, a liquid crystal display device was provided as an example of a display device, but the display device may be related to an organic electroluminescent display, electrophoretic display, PD (plasma display), PALC (plasma addressed liquid crystal display), inorganic electroluminescent display, FED (field emission display), SED (surface-conduction-electron-emitter display), or the like.

In the respective embodiments above, a liquid crystal display device provided with liquid crystal display elements was described as an example, but the present invention can also be applied to an organic EL display device constituted by organic EL display elements such as a first electrode (positive electrode), an organic EL layer having a light emitting layer provided on the first electrode, and a second electrode (negative electrode) formed on the organic EL layer.

Furthermore, in the respective embodiments above, the respective configurations used plastic substrates 11 and 15, but glass substrates may be used instead.

Furthermore, in the respective embodiments above, the configuration has a polarizing plate provided on the surface of the CF substrate 3 opposite to the liquid crystal layer 4, but the polarizing plate may be provided on the surface of the TFT substrate 2 opposite to the liquid crystal layer 4.

### INDUSTRIAL APPLICABILITY

As described above, the present invention is especially useful for a display device equipped with a touch panel that can detect a touch location where a pen or a finger touches a display surface.

### DESCRIPTION OF REFERENCE CHARACTERS

1 liquid crystal display device equipped with a touch panel
2 TFT substrate
3 CF substrate
4 liquid crystal layer
5 sealing member
12 display element layer
10 CF element layer
17 film substrate
20 liquid crystal display panel (display panel)
25 liquid crystal display panel (display panel)
30 adhesive layer
30a outer edge portion of an adhesive layer
34 touch panel
34a outer edge portion of a touch panel
35 adhesive layer (another adhesive layer)
35a outer edge portion of an adhesive layer
36 protective plate
40 film substrate (another film substrate)
42 conductive film
43 conductive film (another conductive film)

1. A display device equipped with a touch panel, comprising:
a display panel provided with a display element;
an adhesive layer provided on the display panel; and
a touch panel having a flexible film substrate disposed on said adhesive layer and a conductive film for the touch panel disposed on said flexible film substrate, the touch panel being bonded to the display panel via the adhesive layer,
wherein an outer shape of the adhesive layer is larger than an outer shape of the touch panel in a plan view.

2. The display device equipped with a touch panel according to claim 1,
wherein the touch panel further comprises:
a second conductive film for the touch panel provided so as to face the conductive film for the touch panel, an air layer or a resin layer being defined therebetween;
a second flexible film substrate disposed on said second conductive film for the touch panel, said second conductive film for the touch panel and said second flexible substrate forming a portion of the touch panel;
a second adhesive layer provided on a surface of said second flexible film substrate opposite to the display panel; and
a protective plate bonded to the touch panel via said second adhesive layer, and
wherein an outer shape of the second adhesive layer is larger than an outer shape of the touch panel in a plan view.

3. The display device equipped with a touch panel according to claim 2, wherein the protective plate is a glass panel.

4. The display device with a touch panel according to claim 1, wherein the display element is a liquid crystal display element.

5. The display device with a touch panel according to claim 1, wherein the display element is an organic electroluminescent display element.

6. The display device with a touch panel according to claim 1, wherein the touch panel is a capacitive type touch panel.

7. The display device with a touch panel according to any claim 2, wherein the display element is a liquid crystal display element.

8. The display device with a touch panel according to claim 3, wherein the display element is a liquid crystal display element.

9. The display device with a touch panel according to claim 2, wherein the display element is an organic electroluminescent display element.

10. The display device with a touch panel according to claim 3, wherein the display element is an organic electroluminescent display element.
